(19) United States
(12) Patent Application Publication
(10) Pub. No.: US 2003/0164534 A1
(43) Pub. Date: Sep. 4, 2003

(54) Method for manufacturing semiconductor device using two orientation flats

(76) Inventors: Yasushi Urakami, Tokai-city (JP); Shoichi Yamauchi, Obu-city (JP); Toshio Sakakibara, Nishio-city (JP)

Correspondence Address: POSZ & BETHARDS, PLC, 11250 ROGER BACON DRIVE, SUITE 10, RESTON, VA, 20190, US

(21) Appl. No.: 10/383,741

(22) Filed: Mar. 10, 2003

Related U.S. Application Data
(63) Continuation of application No. 09/804,086, filed on Mar. 13, 2001, now abandoned.

(30) Foreign Application Priority Data
Mar. 16, 2000 (JP) 2000-79348
Nov. 24, 2000 (JP) 2000-358186

(51) Int. Cl. H01L 29/04

(52) U.S. Cl. 257/627

(57) ABSTRACT

A semiconductor substrate has a main surface oriented to {1 1 1} face, a first orientation flat formed on a peripheral portion of a semiconductor substrate and oriented to one of {1 1 1} face and {1 1 2} face perpendicular to the {1 1 0} face. It is easy to select (determine) {1 1 1} face for forming a trench in the semiconductor substrate based on the first orientation flat. In addition, the trench whose face is oriented to {1 1 1} face has few defects on its inner surface.

### CROSS REFERENCE TO RELATED APPLICATIONS

This application is a continuation of U.S. patent application Ser. No. 09/804,086, which was filed on Mar. 13, 2001.

This application is based upon Japanese Patent Application Nos. 2000-79348 filed on Mar. 16, 2000, and 2000-358186 filed on Nov. 24, 2000, the contents of which are incorporated herein by reference.

### BACKGROUND OF THE INVENTION

This invention relates to a substrate processing technique for forming a semiconductor device.

It becomes possible to form high-aspect trenches in a semiconductor substrate in accordance with improvement of an etching technique in a semiconductor device process. Thus, it is able to isolate elements adjoining each other in a wafer with the trench.

Trench isolation can miniaturize a region for element isolation in comparison with element isolation by LOCOS (LOCal Oxidation of Silicon) oxide. Especially, in an integrated circuit with bi-polar transistors having a buried collector layer, the trench isolation can reduce about 80% of the region for element isolation in comparison with element isolation by LOCOS oxide, whereby an integration degree of semiconductor element is improved.

A conventional method for forming trench in the semiconductor substrate is shown in FIGS. 26A to 26D. First, as shown in FIG. 26A, a thermal oxidation film 102 is formed on a main surface of a semiconductor substrate 101, then, an oxide film 103 is formed on the thermal oxidation film 102 by means of CVD (Chemical Vapor Deposition). Next, as shown in FIG. 26B, a resist pattern 104 having an opening is formed on the oxide film 103, then, an exposing portions of the oxide film 103 and the thermal oxidation film 102 exposed to the opening are removed by etching by using the resist pattern 104 as a mask. Thus, an etching mask made up of the oxide film 103 and the thermal oxidation film 102 is formed on the semiconductor substrate 101.

Next, as shown in FIG. 26C, a trench 105 is formed in the semiconductor substrate 101 by anisotropic dry etching through an opening of the etching mask. This dry etching is carried out in ECR (Electron Cyclotron Resonance) plasma etching apparatus, or ICP (Inductively Coupled Plasma) etching apparatus.

After that, a semiconductor device is formed by a subsequent process, for example, a trench isolation forming process for burying inside the trench with an isolation film material, a capacitor forming process for burying inside the trench with an electrode forming material, or an epitaxial layer forming process for burying inside the trench with a semiconductor material.

However, a crystal defect layer 106 having bumpy surface is formed on a surface portion of sidewalls of the trench 105, because a lot of dangling-bonds are formed in the semiconductor substrate 101 during the formation the trench 105. Thus, leakage current occurs and characteristic of the semiconductor device becomes worse.

JP-A-7-106414 teaches a method for removing crystal defects in the crystal defect surface 106 formed on the surface of sidewall of the trench.

According to that publication, the way to remove the crystal defects has a first step for removing the surface of the sidewall of the trench by about 0.2 μm by means of CDE (Chemical Dry Etching) after forming the trench, a second step for removing the crystal defects by removing a sacrificial oxide film of about several hundred ∪ formed by a sacrificial oxide treatment, a third step for reconstructing of semiconductor crystallinity by annealing disordered silicon crystal in nitrogen atmosphere.

According to the method described above, the crystal defect layer can be removed completely if a thickness of the sacrificial oxide film formed by the sacrificial oxide treatment is sufficient. However, stress concentration occurs easily in a part of the sidewalls of the trench after removing the sacrificial oxide film. As a result, if the sacrificial oxide treatment is carried out so as not to cause the stress concentration, the crystal defects would not be removed completely.

Moreover, cost of this method increases because it needs many steps, for example, the sacrificial oxide treatment and the annealing in nitrogen atmosphere, and because CDE process must be performed for each wafer.

In this connection, the inventors of the present invention studied another method for forming a trench, by which it is difficult to form the crystal defect layer on the surface portion of sidewalls of the trench. As a result, it is found that high isotropy can be attained by performing a wet etching so that the sidewalls of the trench have faces perpendicular to Si {1 1 0} face, whereby the crystal defects can be removed from the surface portion of the sidewalls of the trench. Here, the faces perpendicular to Si {1 1 0} face are, for example, {1 \overline{1} 1} face and (\overline{1} 1 \overline{1})face opposed to the (1 \overline{1} 1) face or (\overline{1} 1 1) face and (1 \overline{1 1}) face opposed to the (\overline{1} 1 1) face.

However, the face orientations of the trench are selected (determined) based on an orientation flat formed on a semiconductor wafer and the orientation flat generally has a (1 0 0) face whose x-ray peak can be detected easily. In this case, it is difficult to select the face orientations of the trench by the orientation flat oriented to (1 0 0) face.

### SUMMARY OF THE INVENTION

This invention has been conceived in view of the background as described above and an object of the invention is to provide a semiconductor substrate on which a trench can be easily formed with sidewalls having described face orientations, and to provide a method for manufacturing semiconductor device using the same.

According to a first aspect of the present invention, a semiconductor substrate has a surface oriented to {1 1 0} face and a first orientation flat oriented to {1 1 1} face or {1 1 2} face perpendicular to the {1 1 0} face, whereby it is easy to select {1 1 1} face when trench is formed. In other words, it is easy to select {1 1 1} face for sidewalls of the trench. The {1 1 1} face has few crystal defects, and so it is good for the surface of the trench.

According to a second aspect of the present invention, the semiconductor substrate has a second orientation flat formed a portion other than that of the first orientation flat, whereby it is easy to distinguish a main surface and a back surface of the semiconductor substrate.

Preferably, the second orientation flat is not parallel with the first orientation flat, or a length of the second orientation flat is different from that of the first orientation flat.

### BRIEF DESCRIPTION OF THE DRAWINGS

Other objects, features and advantages of the present invention will become more apparent from the following detailed description made with reference to the accompanying drawings. In the drawings:

FIG. 1 is a plan view of a semiconductor substrate of a first embodiment;

FIG. 2A is a schematic plan view of a trench, FIG. 2B is a sectional view taken along line IIB-IIB in FIG. 2A;

FIGS. 3A to 3F are sectional views each showing a semiconductor substrate in a stepwise manner for explaining the first embodiment;

FIG. 4 is a plan view of the trench formed by steps shown in FIGS. 3A to 3F;

FIG. 5 is a plan view of a semiconductor substrate of a second embodiment;

FIG. 6 is a plan view of a semiconductor substrate of a third embodiment;

FIG. 7A is a plan view of the semiconductor substrate for explaining surface orientation of its main surface, FIG. 7B is the plan view of a semiconductor substrate for explaining surface orientation of its back surface;

FIG. 8 is a plan view of a semiconductor substrate having a second orientation flat;

FIG. 9 is a plan view of a semiconductor substrate of a forth embodiment;

FIG. 10A is a plan view of a trench of a fifth embodiment, FIG. 10B is a sectional view taken along line XB-XB in FIG. 10A;

FIG. 11A is a plan view of a trench of a sixth embodiment, FIG. 11B is a sectional view taken along line XIB-XIB in FIG. 11A;

FIG. 12A is a plan view of a trench of a seventh embodiment, FIG. 12B is a sectional view taken along line XIIB-XIIB in FIG. 12A;

FIG. 13 is a plan view of a trench of an alternative in the seventh embodiment;

FIG. 14 is a plan view of a trench of an another alternative in the seventh embodiment;

FIG. 15A is a plan view of a trench of a eighth embodiment, FIG. 15B is a sectional view taken along line XVB-XVB in FIG. 15A;

FIG. 16A is a plan view of a trench of a ninth embodiment, FIG. 16B is a sectional view taken along line XVIB-XVIB in FIG. 16A;

FIG. 17A is a plan view of a trench of a tenth embodiment, FIG. 17B is a sectional view taken along line XVIIB-XVIIB in FIG. 17A;

FIG. 18 is a plan view of a trench of an eleventh embodiment;

FIG. 19 is a plan view of a trench of an alternative in the seventh embodiment;

FIG. 20 is a plan view of a trench of another alternative in the eleventh embodiment;

FIG. 21 is a sectional view showing a method for forming a trench;

FIG. 22 is a sectional view showing another method for forming a trench;

FIG. 23 is a sectional view showing another method for forming a trench;

FIG. 24 is a sectional view showing another method for forming a trench;

FIG. 25 is a sectional view of a semiconductor substrate for forming a trench by the other way;

FIGS. 26A to 26D are sectional views each showing a semiconductor substrate in a stepwise manner for explaining a related art.

### DESCRIPTION OF THE EMBODIMENTS

Specific embodiments of the present invention will now be described hereinafter with reference to the accompanying drawings in which the same or similar component parts are designated by the same or similar reference numerals.

Moreover, in notation of face orientation, (h k 1) face denotes a specific face orientation, and {h k 1} face denotes equivalent faces based on symmetry. Concretely, {hk1} face denotes one or all of (h k 1) face, (h \overline{k} 1) face, (h k \overline{1}) face, (h \overline{k 1}) face, (\overline{h} k 1) face, (\overline{h k}1) face, (\overline{h} k \overline{1}) face, and (\overline{h k 1}) face.

First Embodiment

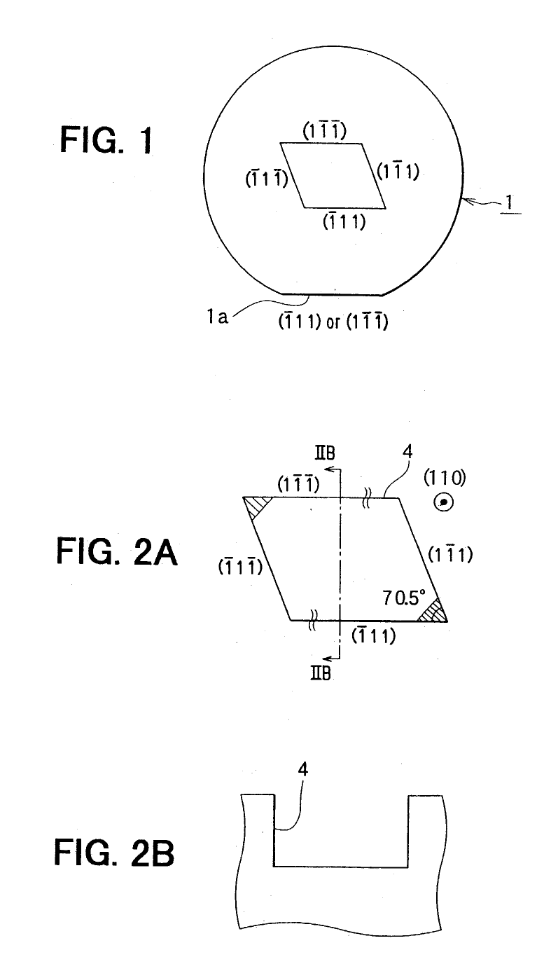

Referring to FIG. 1, a silicon semiconductor substrate 1 has Si (1 1 0) face whose crystal axis orientation is<1 1 0>direction and an orientation flat (a first orientation flat) 1a that is formed by cutting along (\overline{1} 1 1) face or (1 \overline{1 1}) face perpendicular to (1 1 0) face. Namely, face orientations to be selected (determined) as sidewalls of a trench 4 are parallel with the orientation flat 1a.

Therefore, it is easy to select (\overline{1} 1 1) face and (1 \overline{1 1}) face for the sidewall of the trench 4 based on the first orientation flat 1a. Thus, a wet etching can be appropriately performed for forming the trench 4.

Hereinafter, the sidewalls of the trench 4 parallel to the first orientation flat 1a are referred to as main sidewalls, and the sidewalls non-parallel to the first orientation flat 1a are referred to as other sidewalls or end portions. The trench 4 is defined by two main sidewalls parallel with each other, two other sidewalls parallel with each other, and a bottom face appeared after the trench etching. Basically, the main sidewalls are longer than the other sidewalls. The main sidewalls are formed, for example, along (\overline{1} 1 1) face and (1 \overline{1 1}) face, the other sidewalls are formed along (\overline{1}1 \overline{1}) face and (1 \overline{1} 1) face as shown in FIG. 2A. An angle defined by (1 \overline{1} 1) face and (\overline{1} 1 1) face at a surface of the semiconductor substrate 1 is 70.5°. Moreover, a longitudinal direction of the trench 4 is defined along (\overline{1} 1 1) face and (1 \overline{1 1}) face.

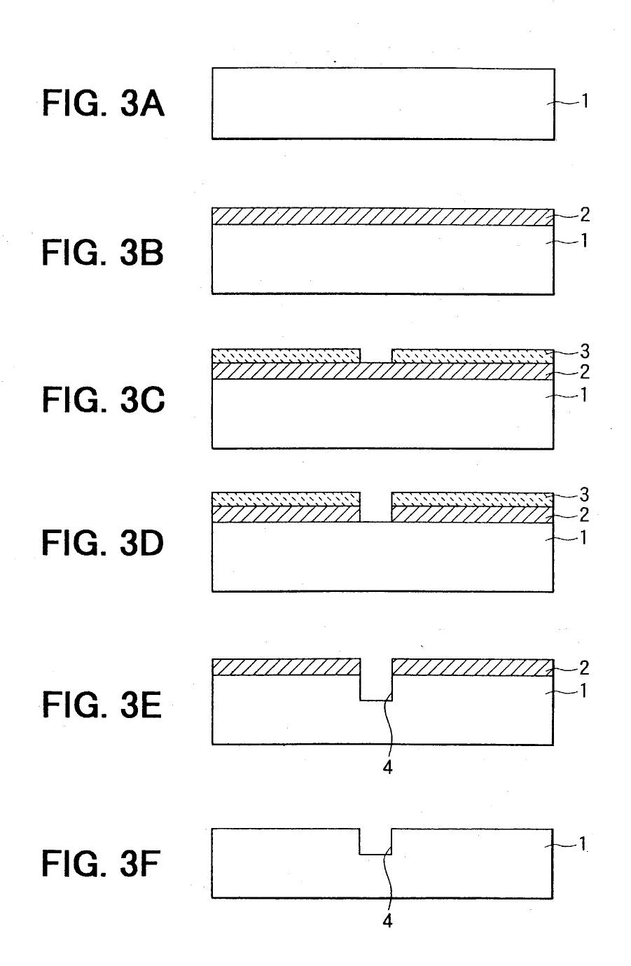

A method for processing the trench will be explained concretely based on FIGS. 3A to 3F.

Step in FIGS. 3A and 3B

The semiconductor substrate 1 is prepared. A mask 2 made of silicon dioxide or silicon nitride is formed on a surface of the semiconductor substrate 1 by using of CVD(Chemical Vapor Deposition) or PVD (Physical Vapor Deposition). The silicon oxide as the mask 2 may be formed by thermal oxidation.

The mask 2 is utilized as an etching mask against anisotropic etching solution in following step. Therefore, a thickness of the mask 2 is decided by an etching selectivity of the mask 2 against silicon. In the case that the silicon dioxide is used as the mask 2, and 22 wt. % TMAH (TetraMethylAmmonium Hydoroxide) solution at 90° C. is used as the etching solution, the etching selectivity of the mask 2 against silicon becomes 1/2000. As a result, the silicon dioxide mask 2 should be formed with a thickness of 0.01 μm or more if silicon is etched 20 μm.

Step in FIG. 3C

After photo-resist 3 is applied on the mask 2, a pattern having an opening along (\overline{1} 1 1) face and (1 \overline{1 1}) face is exposed on the photo-resist 3, and this photo-resist 3 is developed. It is easy to determine a direction of the pattern because the first orientation flat 1a has (\overline{1} 1 1) face or (1 \overline{1 1}) face perpendicular to (1 1 0) face.

Step in FIG. 3D

The mask 2 is dry-etched by using the photo-resist 3 as a mask so that a predetermined portion of the mask 2 corresponding to a trench-forming portion is opened. After that, the photo-resist 3 is removed from the semiconductor substrate 1.

Step in FIG. 3E

A trench 4 is formed in the semiconductor substrate 1 by wet etching performed by using the TMAH solution or a KOH solution with the mask 2 as the etching mask. The anisotropic solution such as the TMAH and KOH etches Si {1 1 1} face very slowly in comparison with other Si face. As a result, the sidewalls of the trench 4 are formed perpendicularly to Si (1 1 0) face with the solution described above.

According to this embodiment, the main sidewalls are formed along (\overline{1} 1 1) face and (1 \overline{1 1}) face as shown in FIG. 2A, and the main sidewalls are formed perpendicularly to (1 1 0) face as shown in FIG. 2B.

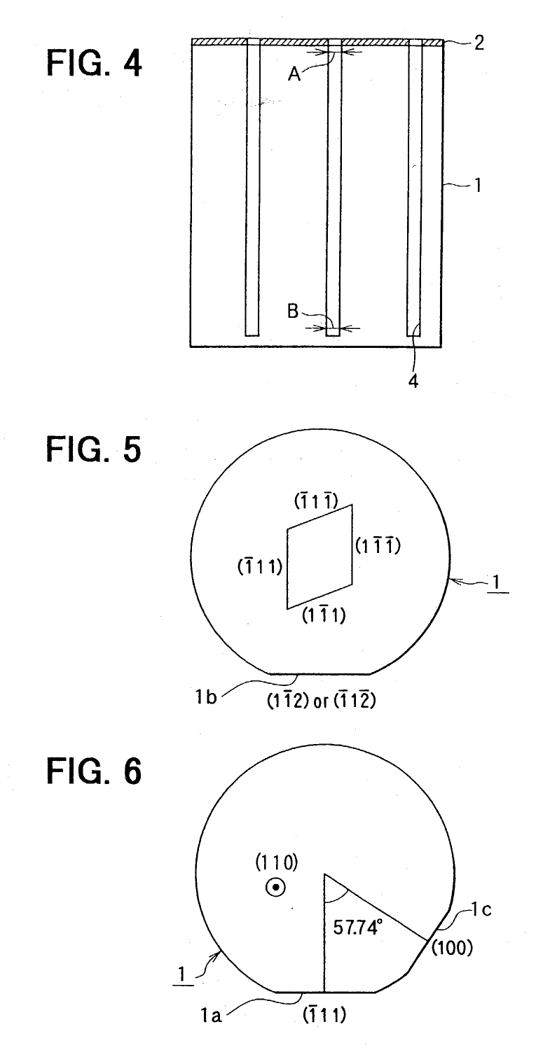

FIG. 4 shows a schematic diagram of a sectional view based on SEM (Scanning Electron Microscope) image of a silicon semiconductor substrate to which the trench etching is performed with the mask 2 having a 1.0 μm opening width and 22 wt. % TMAH solution of 90° C.

According to the SEM image of FIG. 4, a depth of the trench 4 is 110.5±3.9 μm. A width A of the trench 4 at an upper portion is 4.2±0.2 μm, and a width B of the trench 4 at a bottom portion is 4.1±0.1 μm. As a result, an aspect ratio of the trench 4 becomes about 26. A ratio of an amount of the etching in a direction perpendicular to the surface of the semiconductor substrate 1 to an amount of the etching toward a direction parallel with the surface of the semiconductor substrate 1 is about 66:1. Therefore, if the opening width of the mask 2 is formed as narrow as possible, the trench would be formed at a maximum aspect ratio 33.

Process in FIG. 3F

After the semiconductor substrate 1 is cleaned by pure water, the mask 2 is removed from the surface of the semiconductor substrate 1. Finally, the semiconductor substrate 1 having the trench 4 is completed.

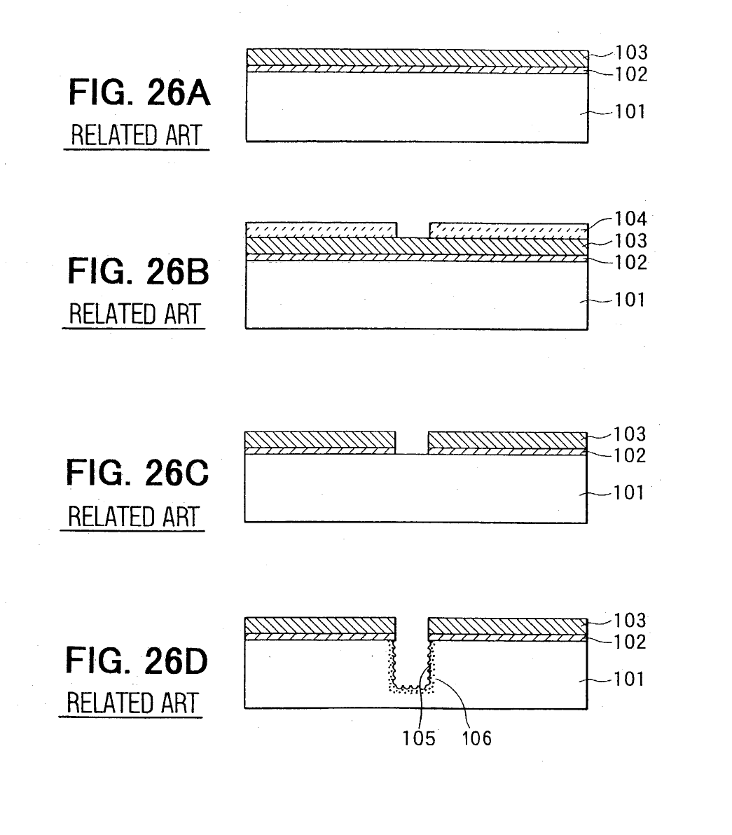

As a result, the trench 4 has the sidewalls perpendicular to Si (1 1 0) face. Moreover, bumps formed on the surface of the sidewall can be miniaturized in atomic level in comparison with the conventional method as shown in FIGS. 26A to 26D. Furthermore, a density of crystal defects in the surface portion of the sidewalls of the trench becomes the same as that of bulk portion of the semiconductor substrate 1.

Therefore, deterioration in electric characteristics of devices caused by the crystal defects is suppressed when the semiconductor device having trench type gate electrode, trench capacitor or trench isolation are formed by using the semiconductor substrate 1 in this embodiment.

Second Embodiment

Referring to FIG. 5, a semiconductor substrate 1 has Si (1 1 0) face whose crystal axis orientation is<1 1 0>direction, and an orientation flat (a first orientation flat) 1b whose face corresponds to (1 \overline{1} 2) face or (\overline{1} 1 \overline{2}) face perpendicular to (1 1 0) face. Namely, a face orientation to be as a sidewall of a trench is perpendicular to the orientation flat 1b.

Therefore, it is easy to select (\overline{1} 1 1) face and (1 \overline{1 1}) face for the sidewalls of the trench based on the first orientation flat 1b. A method of the trench in the second embodiment is the same as that of the first embodiment. Accordingly, the same advantages as those of the first embodiment can be attained.

Third Embodiment

A schematic diagram of a semiconductor substrate 1 in the third embodiment is shown in FIG. 6. This semiconductor substrate 1 has not only the first orientation flat 1a but a second orientation flat 1c whose face is (100) face. The second orientation flat 1c is formed based on detecting (1 0 0) face by means of x-ray diffraction before the semiconductor substrate 1 is cut out of an ingot of silicon.

A length of the second orientation flat 1c is different from that of the first orientation flat 1a. In this embodiment, a chord of the second orientation flat 1c is shorter than that of the first orientation flat 1a formed parallel or perpendicular to the {1 1 1} face.

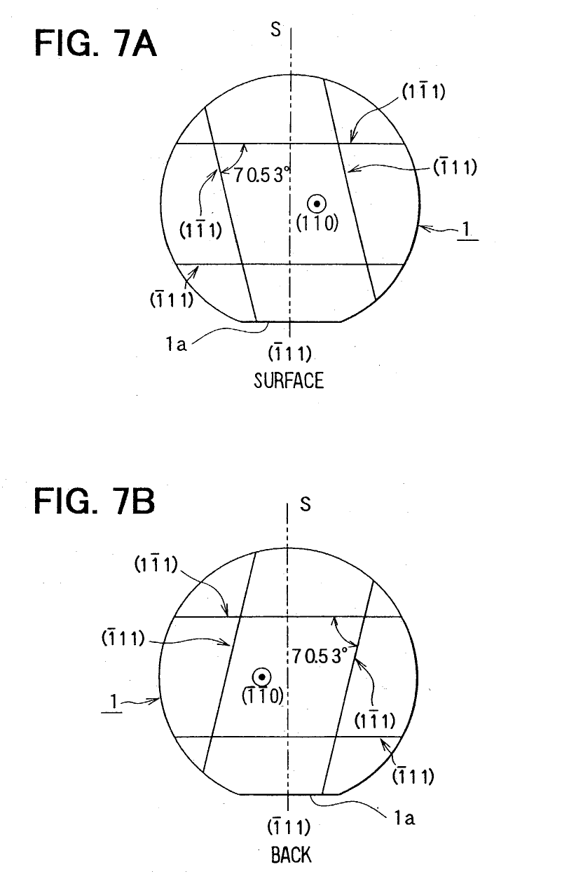

FIG. 7A shows each face orientation in the semiconductor substrate 1 viewed from a main surface side, and FIG. 7B shows each face orientation in the semiconductor substrate 1 viewed from a back surface side.

According to FIGS. 7A and 7B, {1 1 1} faces are not symmetric with respect to a virtual line S defined to pass though a center of the semiconductor substrate 1 and a center of the orientation flat 1a. Therefore, a coordinate axis on the main surface side in the semiconductor substrate 1 is different from that on the back surface side in the semiconductor substrate 1.

In other words, in the condition that orientation flat 1a is set to (\overline{1} 1 1) face, a direction of an intersection line defined by Si (1 1 0) face and the {1 1 1} faces perpendicular to the Si (1 1 0) face in the main surface side is different from that of an intersection line defined by Si (1 1 0) face and the {1 1 1} faces perpendicular to the Si (1 1 0) face in the back surface side.

Namely, the trench shape surrounded by {1 1 1} faces at the main surface side shown in FIG. 7A does not correspond to that at the back surface side shown in FIG. 7B.

Therefore, the trench is not formed desirably when the back surface side is erroneously recognized as the main surface side. Therefore, a marking is required to distinguish the main surface side and the back surface side of the semiconductor substrate 1.

In this embodiment, the second orientation flat 1c having a direction different from that of the first orientation flat 1a is used as the marking described above. Moreover, the length of the first orientation flat 1a is different from that of the second orientation flat 1c, whereby it is able to distinguish the main surface side and the back surface side. Thus, the trench is formed on a predetermined surface side of the semiconductor substrate 1 with the first and second orientation flats.

Apparatuses used in semiconductor process usually recognize an orientation flat formed in a semiconductor wafer and adjust a mask to the wafer based on the orientation flat. Moreover the apparatuses also recognize a longest chord formed in the wafer as the orientation flat when a notch is formed on a peripherally portion of the wafer.

Therefore, it is preferable that the length of the second orientation flat 1c for distinguishing the main surface side and the back surface side is shorter than that of an orientation flat parallel or perpendicular to the {1 1 1} face i.e., the first orientation flat 1a.

In this embodiment, although the second orientation flat 1c for distinguishing the main surface side and the back surface side is formed on (1 0 0) face because this face is easily specified by x-ray diffraction, other faces are applied to a face for distinguishing the main surface side and the back surface side.

In other words, an angle defined by a normal line of the first orientation flat 1a formed on (\overline{1} 1 1) face or (1 \overline{1 1}) face and a normal line of the second orientation flat 1c formed on (1 0 0) face is 54.74° in this embodiment; however, an angle defined by the first orientation flat 1a and the other orientation flat may be an angle different from 54.74°.

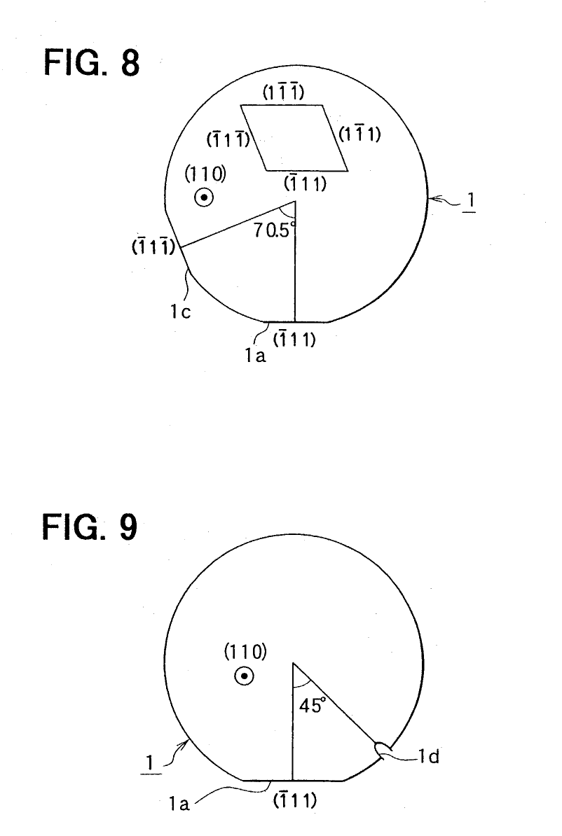

As shown in FIG. 8, the second orientation flat may be formed on (\overline{1} 1 \overline{1}) face non-parallel with (\overline{1} 1 1) face instead of formed on (1 0 0) face. In this case, when a parallelogram is formed in a mask for wet etching, it is easy to confirm a positional relationship of four sides of the parallelogram by judging whether each of the four sides is parallel with the first and second orientation flat 1a or 1c. That is, it is easy to determine whether the parallelogram is an accurate pattern or not. Moreover, (\overline{1} 1 \overline{1}) face can be specified easily by x-ray diffraction, and therefore it is easy to form the second orientation flat 1c on this face.

Moreover, it is preferable that the first and second orientation flats 1a and 1c should not be formed in parallel with each other. Because if the first and second orientation flats 1a and 1c is formed in parallel with each other, the main and back surface sides can not be recognized.

In this embodiment, it is preferable that an angle defined by a normal line direction of the first orientation flat 1a formed along (\overline{1} 1 1) face or (1 \overline{1 1}) face and a normal line of the second orientation flat 1c is in a range of 2° to 178° or 182° to 358°.

Fourth Embodiment

Referring to FIG. 9, a semiconductor substrate 1 has not only the first orientation flat 1a formed on {1 1 1} face but a notch 1d formed on a periphery of the substrate 1 instead of the second orientation flat for distinguishing the main surface side and the back surface side described in the third embodiment.

This notch 1d is also useful for distinguishing the main surface side and the back surface side like the second orientation flat described in the third embodiment.

In this embodiment, although an angle defined by a line defined to pass through the center of the substrate 1 and the notch 1d and the normal line of the orientation flat 1a is 45°, it is not limited to that.

Fifth Embodiment

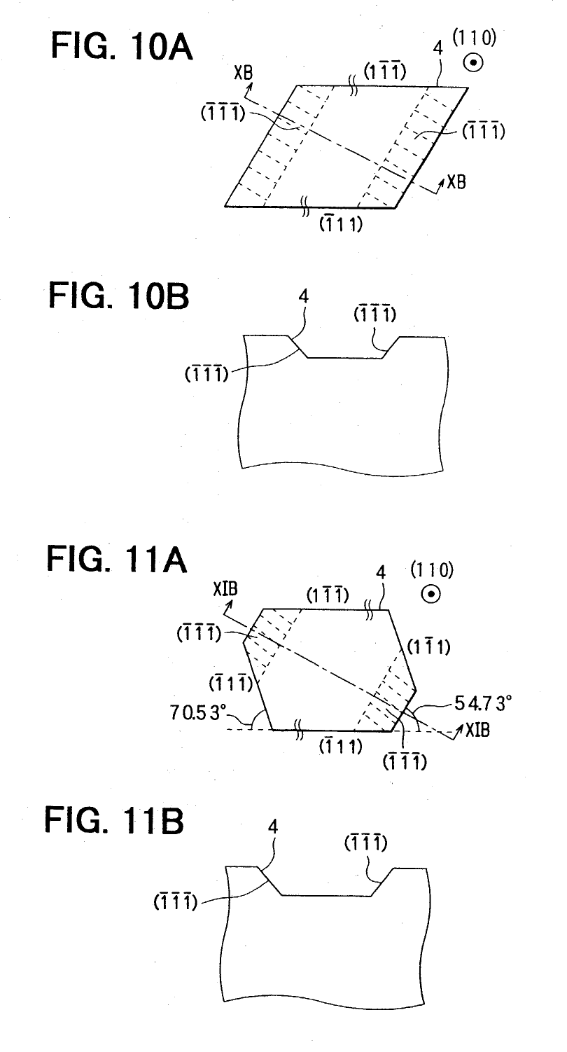

Fifth embodiment will be explained based on FIGS. 10A and 10B in comparison with the first embodiment. A form of trench in this embodiment is different from that of the trench 4 in the first embodiment.

In the first embodiment, the main sidewalls of the trench 4 are formed along (\overline{1} 1 1) face and (1 \overline{1 1}) face, and the other sidewalls (end portions) of the trench 4 are formed along (\overline{1} 1 \overline{1}) face and (1 \overline{1}1) face. As a result, the angle defined by (1 \overline{1} 1) face and (\overline{1} 1 1) face at a surface of the semiconductor substrate 1 is 70.5°.

To the contrary, in this embodiment, the end portions of the trench 4 are formed along an intersection line defined by (1 1 0) face and (\overline{1 1 1}) face. In this case, an angle defined by the intersection line between (1 1 0) face and (\overline{1 1 1}) face and (\overline{1} 1 1) face is 54.7°.

The main sidewalls of the trench 4 are formed along (\overline{1} 1 1) face or (1 \overline{1 1}) face, and formed perpendicularly to Si (1 1 0) face in this embodiment.

However, the trench 4 tapers in a depth direction with the end portions formed on (\overline{1 1 1}) face as shown in FIG. 10B. In other words, hatched portions in FIG. 10A are shallower than the other portion, whereby it is notable to make semiconductor elements in the hatched portions. Therefore, it is preferable to form the trench 4 not as shown in FIGS. 10A and 10B, but as shown in FIG. 2, since the hatched portion of the trench 4 in FIG. 2 is small in comparison with that in FIG. 10A.

Sixth Embodiment

As shown in FIG. 11A and 11B, a plan shape of a trench 4 in this embodiment is modified from that in the fifth embodiment.

The trench 4 in this embodiment has a plan shape of a combination of the trenches in the first and fifth embodiments. Main sidewalls of the trench 4 are formed along (\overline{1} 1 1) face and (1 \overline{1 1}) face. One of other sidewalls (end portions) of the trench 4 is defined by an intersection line between (\overline{1} 1 \overline{1}) face and (1 1 0) face and an intersection line between (\overline{1 1 1}) face and (1 1 0) face. The other of the other sidewalls of the trench 4 is defined by an intersection line between (1 \overline{1} 1) face and (1 1 0) face and an intersection line between (\overline{1 1 1}) face and (1 1 0) face. Thus, the trench 4 in this embodiment has a hexagon plan shape.

The trench 4 is also tapered at (\overline{1 1 1}) face disposed between (\overline{1} 1 \overline{1}) face and (1 \overline{1 1}) face or between (\overline{1} 1 1) face and (1 \overline{1} 1) face.

However, in this embodiment, the tapered portions are small because the other sidewalls also have (\overline{1} 1 \overline{1}) face and (1 \overline{1} 1) face which are perpendicular to (1 1 0) face. Thus, it becomes possible to reduce portions in which semiconductor elements are not able to form, whereby the trench 4 can be made compact in its longitudinal direction.

Seventh Embodiment

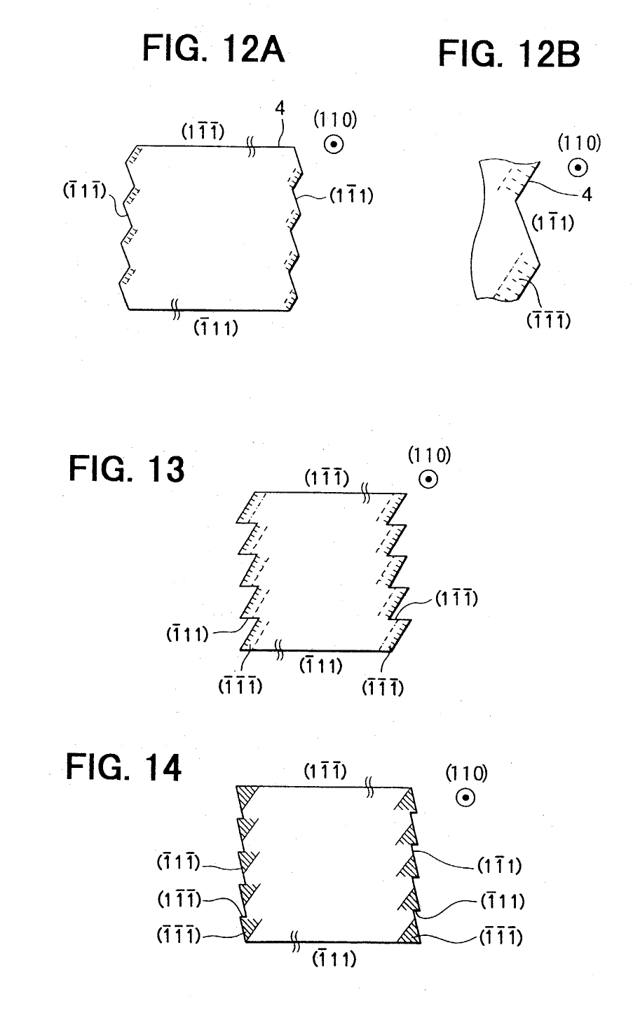

As shown in FIG. 12A and 12B, a plan shape of a trench 4 in this embodiment is modified from that in the sixth embodiment. FIG. 12B is an enlarged view of other sidewalls of the trench 4 in this embodiment.

One of the other sidewalls has a zigzag shape (or notched shape) is defined with two intersection lines. One of the intersection lines is defined by (\overline{1} 1 \overline{1}) face and (1 1 0) face and the other is defined by (\overline{1 1 1}) face and (1 1 0) face, and these two intersection lines are repeated alternately. The other of other sidewalls also has a zigzag shape defined with two intersection lines. One of the intersection lines is defined by (1 \overline{1} 1) face and (1 1 0) face and the other is defined by (\overline{1 1 1}) face and (1 1 0) face, and these two intersection lines are repeated alternately.

In this embodiment, the tapered portions are smaller than those in the sixth embodiment.

Even when the trench 4 has a plan shape different from the plan view of the trench 4 in this embodiment, it will be able to obtain the same effect as that described in this embodiment.

Some of modifications will be shown in FIGS. 13 and 14. In FIG. 13, one of other sidewalls (end portions) of a trench 4 is defined with two intersection lines. One of the intersection lines is defined by (\overline{1 1 1}) face and (1 1 0) face and the other is defined by (\overline{1} 1 1) face and (1 1 0) face, and these two intersection lines are repeated alternately. The other of the other sidewalls is also defined with two intersection lines. One of the intersection lines is defined by (\overline{1 1 1}) face and (1 1 0) face and the other is defined by (1 \overline{1 1}) face and (1 1 0) face, and these two intersection lines are repeated alternately.

In FIG. 14, one of other sidewalls (end portions) of a trench 4 is defined with two intersection lines. One of the intersection lines is defined by (1 \overline{1} 1) face and (1 1 0) face and the other is defined by (\overline{1} 1 1) face and (1 1 0) face, and these two intersection lines are repeated alternatively. The other of other sidewalls is also defined with two intersection lines. One of the intersection lines is defined by (\overline{1} 1 \overline{1}) face and (1 1 0) face and the other is defined by (1 \overline{1 1}) face and (1 1 0) face, and these two intersection lines are repeated alternately.

Eighth Embodiment

In this embodiment, a trench 4 different from the trenches 4 described in the first to seventh embodiments will be explained.

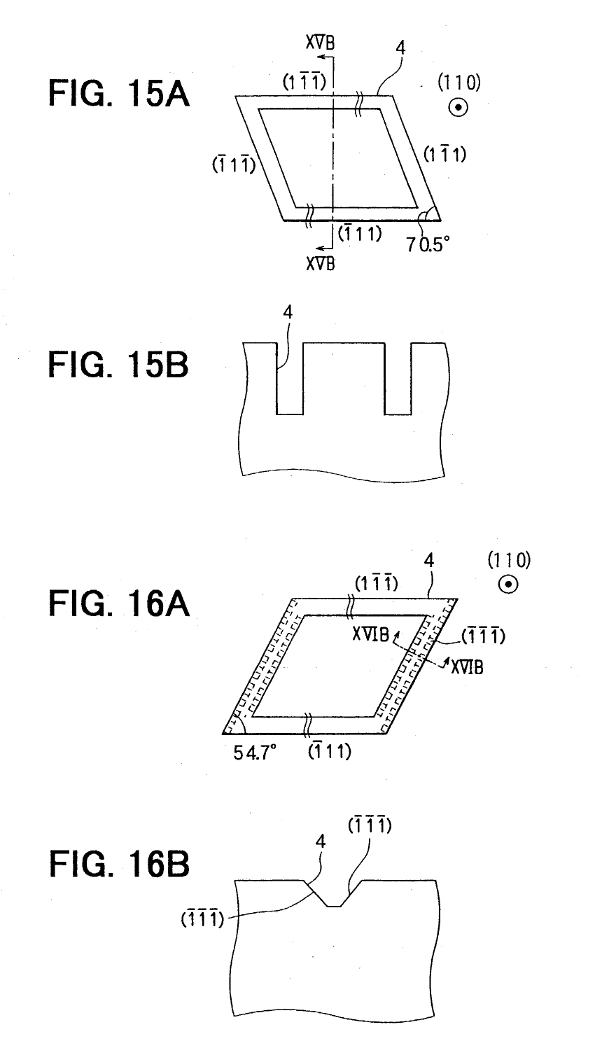

The trenches 4 in the above described embodiments are formed in a line shape pattern, while a trench 4 in this embodiment is formed in a frame shape pattern as shown in FIGS. 15A and 15B.

Each long of the trench 4 is formed along (1 \overline{1 1}) face or (\overline{1} 1 1) face, and each short side of the trench 4 is formed along (\overline{1} 1 \overline{1}) face or (1 \overline{1} 1) face. Thus, it is able to obtain the same effect as that described in the second embodiment.

Ninth Embodiment

In this embodiment, a frame shape pattern different from that described in the eighth embodiment will be explained.

As shown in FIGS. 16A and 16B, each long side of the trench 4 is formed along (1 \overline{1 1}) face or (\overline{1} 1 1) face. On the other hand, each short side of the trench 4 is defined with an intersection line defined by (\overline{1 1 1}) face and (1 1 0) face. In this embodiment, it is able to obtain the same effect as that caused by the trench 4 shown in FIGS. 10A and 10B. Moreover, since the trench 4 tapers at sidewalls formed on (\overline{1 1 1}) face, it is preferable that a plan shape of the trench 4 is formed as that described in the eighth embodiment.

Tenth Embodiment

In this embodiment, a frame shape pattern different from that described in the eighth or ninth embodiment will be explained.

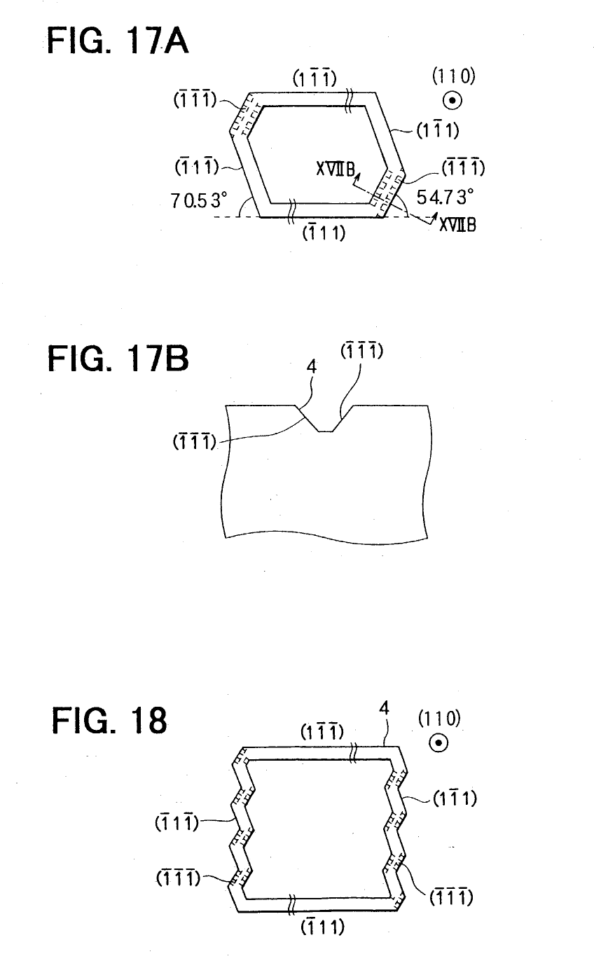

As shown in FIGS. 17A and 17B, each long side of the trench 4 is formed along (1 \overline{1 1}) face or (\overline{1} 1 1) face. On the other hand, one short side of the trench 4 is defined with two intersection lines. One of the intersection lines is defined by (\overline{1 1 1}) face and (1 1 0) face, and the other is defined by (\overline{1} 1 \overline{1}) face and (1 1 0) face. The other short side of the trench 4 is also defined with two intersection lines. One of the intersection lines is defined by (\overline{1 1 1}) face and (1 1 0) face, and the other is defined by (1 \overline{1} 1) face and (1 1 0) face. In this embodiment, it is able to obtain the same effect as that caused by the trench 4 shown in FIGS. 11A and 11B.

Eleventh Embodiment

In this embodiment, a trench 4 having a frame shape pattern different from that described in the tenth embodiment will be explained referring to FIG. 18.

One of short sides of the trench 4 is defined with two intersection lines. One of the intersection lines is defined by (\overline{1 1 1}) face and (1 1 0) face and the other is defined by (\overline{1} 1 \overline{1}) face and (1 1 0) face, and these two intersection lines are repeated alternately. The other of the short sides is also defined with two intersection lines. One of the intersection lines is defined by (\overline{1 1 1}) face and (1 1 0) face and the other is defined by (1 \overline{1} 1) face and (1 1 0) face, and these two intersection lines are repeated alternately. Thus, the other sidewalls of the trench 4 are notched as shown in FIG. 18.

In this embodiment, it is able to obtain the same effect as that caused by the trench 4 shown in FIGS. 12A and 12B.

Even when a trench has a plan shape different from the plan shape of the trench 4 in this embodiment, it will be able to obtain the same effect as that described in this embodiment.

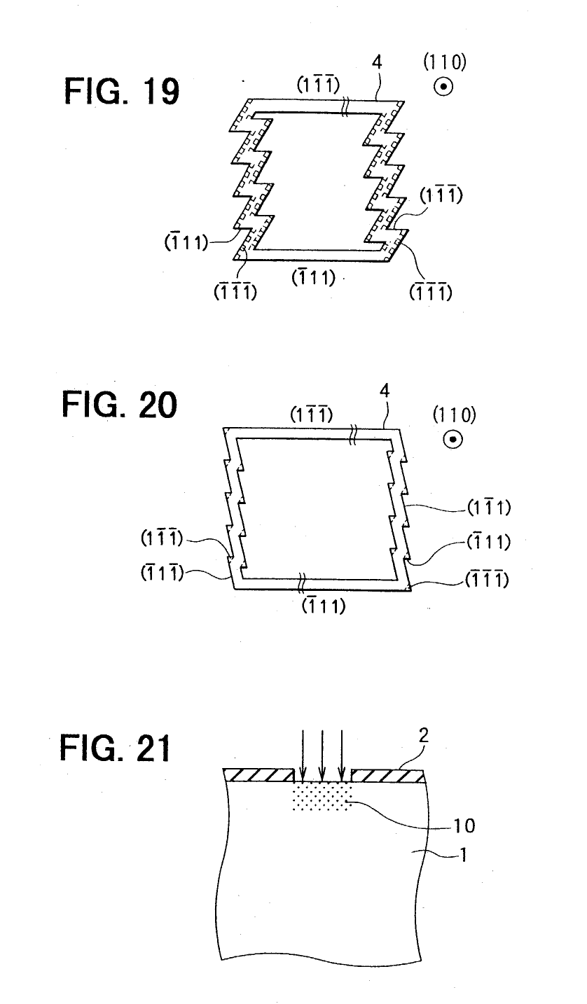

Some of modifications will be shown in FIGS. 19 and 20. In FIG. 19, one of short sides of a trench 4 is defined with two intersection lines. One of the intersection lines is defined by (\overline{1 1 1}) face and (1 1 0) face and the other is defined by (\overline{1} 1 1) face and (1 1 0) face, and these two intersection lines are repeated alternately. The other of short sides of the trench 4 is also defined with two intersection lines. One of the intersection lines is defined by (\overline{1 1 1}) face and (1 1 0) face and the other is defined by (1 \overline{1 1}) face and (1 1 0) face, and these two intersection lines are repeated alternately.

In FIG. 20, one of short sides of a trench 4 is defined with two intersection lines. One of the intersection lines is defined by (1 \overline{1} 1) face and (1 1 0) face and the other is defined by (\overline{1} 1 1) face and (1 1 0) face, and these two intersection lines are repeated alternately. The other of the short sides is also defined with two intersection lines. One of the intersection lines is defined by (\overline{1} 1 \overline{1}) face and (1 1 0) face and the other is defined by (1 \overline{1 1}) face and (1 1 0) face, and these two intersection lines are repeated alternately.

In the above-mentioned embodiments, although a Si substrate oriented to (1 1 0) face is used as the semiconductor substrate 1, this is one example of {1 1 0} faces. Each face of {1 1 0} faces can be applied to the face orientation of the semiconductor substrate 1. In this case, an orientation flat is formed on {1 1 1} face or {1 1 2} face, and if face orientations of sidewalls of a trench are parallel or perpendicular to the orientation flat, the same effect as that explained in the embodiments described above can be attained.

For example, when the orientation flat is oriented to (1 \overline{1} 1) face or (\overline{1} 1 \overline{1}) face, main sidewalls of the trench may be formed on opposing faces oriented to (1 \overline{1} 1) face and (\overline{1} 1 \overline{1}) face by an anisotropic wet etching.

Otherwise, when the orientation flat having (1 \overline{1 2})face or (\overline{1} 1 2) face is disposed perpendicular to (1 \overline{1} 1) face or (\overline{1} 1 \overline{1}) face, the main sidewalls of the trench may be formed on opposing faces oriented to (1 \overline{1} 1) face and (\overline{1} 1 \overline{1}) face by the anisotropic wet etching.

As shown in FIG. 21, a defect layer 10 may be formed by ion implantation on a region for forming the trench before conducting the wet etching to improve an anisotropy of the wet etching.

This defect layer 10 improves an etching rate in depth direction. Because bonds among Si atoms, which must be cut during the trench etching, are reduced by forming dangling bonds in the ion implantation step. Ion species used in the ion implantation are preferably selected among Si and rare gas elements like Ar and Xe because these ion species do not have a great influence to device characteristics.

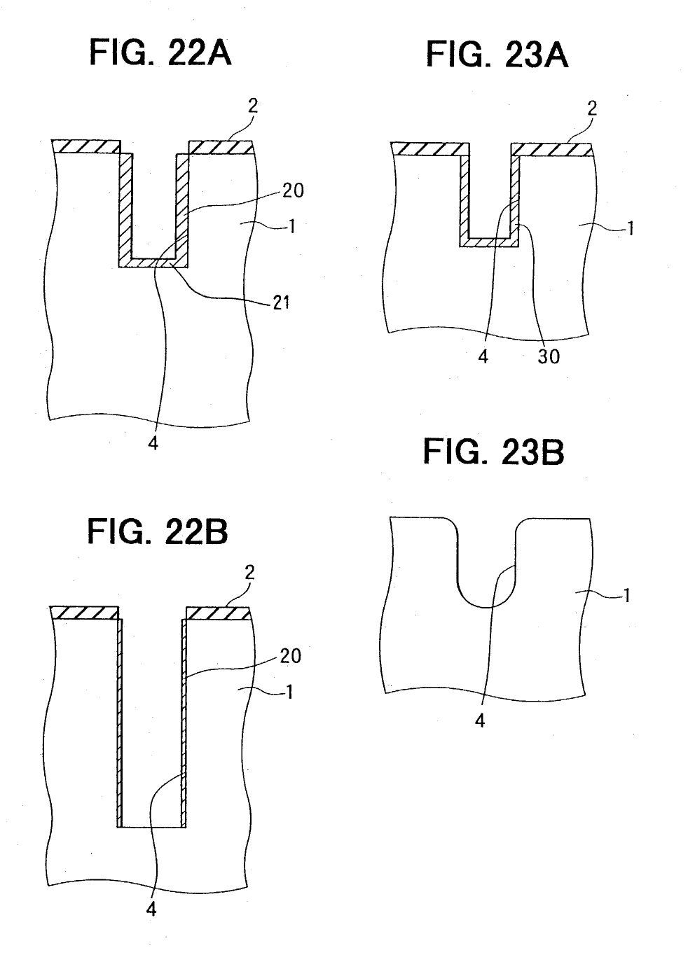

A method as shown in FIGS. 22A and 22B also can be applied to the wet etching of the trench to improve the aspect ratio of the trench.

First, after the wet etching is conducted to form a trench at a predetermined depth, oxidation of inner surface of the trench is carried out. In this case, main sidewalls of the trench are oriented to (1 1 1) face and bottom face of the trench is oriented to (1 1 0) face. Further an oxidation rate of (1 1 1) face is faster than that of (1 1 0) face. Therefore, an oxide 20 formed on the main sidewalls is thicker than an oxide 21 formed on the bottom face.

Subsequently, the oxide 20 and the oxide 21 are etched by HF treatment. In this case, when the oxide 21 is removed completely, the oxide 20 remains because of a different thickness between the oxides 20 and 21. Therefore, the oxide etching is stopped when the oxide 21 is removed completely so as to leave the oxide 20 on the sidewalls. Then, the wet etching of the trench 4 is carried out again, and after that, the oxidation and the HF treatment are carried out again. Namely, a chain process composed the wet etching of the trench, the oxidation of inner surface of the trench, and the HF treatment is repeated. In this case, the wet etching is carried out while protecting the main sidewalls. Therefore, the wet etching is continued with a suppressed wet etching rate in the lateral direction of the trench, and with an enhanced wet etching rate in the depth direction. As a result, the aspect ratio of the trench 4 can be improved.

Although, the thermal oxidation is performed for forming the oxides 20 and 21, oxidation by an oxidizing solution also can be applied. For example, The formation of the oxides 20 and 21 is performed for 1-10 minutes by using solution that contains H₂O₂ and H₂SO₄ mixed at a ratio 1:4 as the oxidizing solution.

In this case, the oxidation rate of the main sidewalls is different from that of the bottom face, whereby the oxide 20 becomes thicker than the oxide 21.

When oxidizing solution is used for the oxidation of the inner surface of the trench, the chain process is not complicated because the chain process only uses liquid treatments, whereby it only requires that the substrate is moved from a tub having a liquid to other tub having other liquid.

In the embodiments described above, the trench 4 is formed by wet etching as shown in FIG. 3E, whereby a sectional view of the trench 4 has right-angled corner portions. If necessary, rounding treatment of corner portions may be carried out.

For example, as shown in FIG. 23A, an oxide 30 is formed on inner surface of the trench 4 by thermal oxidation at 1000° C., preferably 1100° C. or more. After that, as shown in FIG. 23B, the oxide 30 is removed by HF solution, so that the corner portions are rounded.

Specially, the corner portions are rounded by viscosity and elasticity of the oxide 30 caused when the oxide 30 is formed at high temperature. These characteristics make the oxide 30 easy to deform, so that oxidation of the oxide 30 progresses uniformly so that angular portions formed on the corner portions or opening portions of the trench are rounded by the oxidation.

By this rounding treatment, it becomes possible to prevent electric field from concentrating on corner portions of trench gate electrode, trench capacitor or dielectric isolation. Moreover, it is easier to fill the trench by dielectric material for the dielectric isolation or by conductive material for an electrode or wiring.

Alternatively, an isotropic etching treatment by CDE or a solution composed of HF and HNO₃ may be performed after the trench is formed, as another method for rounding the corner portions and opening portions in addition to the oxidation treatment described above.

Further, the surface of the trench may be formed by silicon film formed by epitaxial growth.

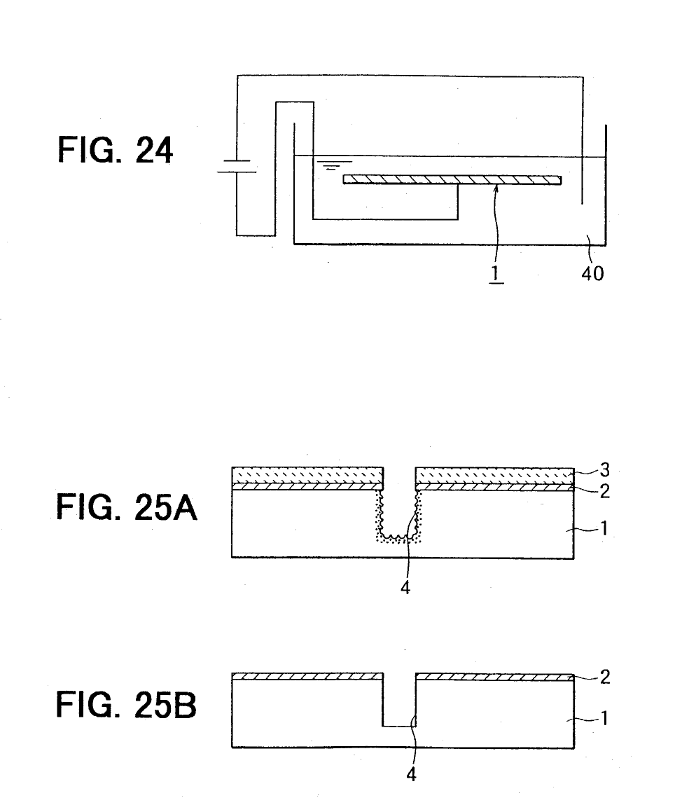

Furthermore, as shown in FIG. 24, an etching mechanism can be changed from anisotropic etching to isotropic etching in anisotropic etching solution 40 by applying voltage between the silicon substrate whose main surface is oriented to (1 1 0) face and the anisotropic etching solution 40, since an oxide film is formed on the silicon substrate by applying the voltage that cause anodic oxidation. In other words, although silicon is etched directly when the voltage is not applied, silicon is etched indirectly because of the oxide film formed on the silicon substrate when the voltage is applied.

The same effect as that described above can be attained in this method. Furthermore, since the oxide film is formed on the substrate by applying the voltage, the trench can be suppressed from being widened by applying pulse voltage having an interval at which oxide film on the sidewalls of the trench is not removed completely. That is, the trench can be suppressed from being widened by utilizing difference in oxidation rate between the bottom face and the sidewalls. Thus, it becomes possible to form the trench having high aspect ratio.

As described above, although wet etching is applied to each embodiment, it does not necessarily to apply wet etching from the beginning. Other way to form the trench will be explained referring to FIGS. 25A and 25B. The processes shown in FIGS. 25A and 25B follow the step shown in FIG. 3D.

After the mask 2 is opened at a trench-forming portion, as shown in FIG. 25A, the trench 4 is formed in an ECR plasma etching apparatus or an ICP plasma etching apparatus.

A bumpy surface is formed on inner surface of the trench 4 after the trench etching is performed. Next, anisotropic etching by using KOH solution of TMAH solution is carried out after the mask 2 is removed. For example, a portion of about 0.5 μm to 2 μm is etched from the inner surface of the trench 4 by 22 wt. % TMAH at 90° C. By this way, the inner surface of the trench 4 can be made smooth.

What is claimed is:

1. A semiconductor substrate comprising:
a main surface oriented to {1 1 0} face;
a first orientation flat formed on a first peripheral portion of a semiconductor substrate, and oriented to one of {1 1 1} face and {1 1 2} face perpendicular to the {1 1 0} face.

2. A semiconductor substrate according to claim 1, further comprising;
a second orientation flat formed on second peripheral portion located different from the first peripheral portion of the semiconductor substrate.

3. A semiconductor substrate according to claim 2, wherein an angle defined between a normal line of the first orientation flat and a normal line of the second orientation flat falls in one of ranges between 2° to 178° or 182° to 358°0.

4. A semiconductor substrate according to claim 2, wherein the second orientation flat is perpendicular to the {1 1 0} face and is non-parallel with the first orientation flat.

5. A semiconductor substrate according to claim 2, wherein the second orientation flat is oriented to {1 0 0} face perpendicular to the {1 1 0} face.

6. A semiconductor substrate according to claim 2, wherein a first chord is defined on the first peripheral portion of the semiconductor substrate by the first orientation flat, and a second chord is defined on the second peripheral portion of the semiconductor substrate by the second orientation flat;
wherein a length of the first chord is different from a length of the second chord.

7. A semiconductor substrate according to claim 1, further comprising:
a notch formed on a second peripheral portion located different from the first peripheral portion of the semiconductor substrate.

8. A semiconductor substrate according to claim 7, wherein an angle defined between a normal line of the first orientation flat and a line defined to pass through a center of the semiconductor substrate and the notch falls in one of 2° to 178° or 182° to 358°.

9. A semiconductor substrate comprising:
a main surface oriented to {1 1 0} face;
a first orientation flat formed on a first peripheral portion of a semiconductor substrate, and oriented to one of {1 1 1} face and {1 1 2} face perpendicular to the {1 1 0} face;
a second orientation flat formed on a second peripheral portion of a semiconductor substrate, and oriented to one of {1 1 1} face and {1 1 0} face and non-parallel with the first orientation flat

10. A semiconductor substrate according to claim 9, wherein a first chord is defined on the first peripheral portion of the semiconductor substrate by the first orientation flat, and the second chord is defined on the second peripheral portion of the semiconductor substrate by the second orientation flat;
wherein a length of the first chord is different from a length of the second chord.

11. A semiconductor substrate according to claim 9, wherein the length of the second chord is shorter than that of the first chord.

12. A method for manufacturing a semiconductor devise using a semiconductor substrate comprising:
preparing a semiconductor substrate having a main surface oriented to {1 1 0} face, a first orientation flat formed on a first peripheral portion of a semiconductor substrate, and oriented to one of {1 1 1} face and {1 1 2} face perpendicular to the {1 1 0} face;
selecting {1 1 1} face on the semiconductor substrate based on the first orientation flat;
forming a trench in the semiconductor substrate by wet etching so that a longitudinal direction of the trench is defined along the {1 1 1} face.

13. A method for manufacturing a semiconductor devise according to claim 12, wherein one of potassium hydroxide (KOH) solution and tetramethylammonium hydroxide (TMAH) solution is used for the wet etching.

14. A method for manufacturing a semiconductor devise according to claim 12, wherein the trench is formed by:
etching the semiconductor substrate to form the trench by wet etching;
forming an oxide film on sidewalls and bottom face of the trench;
removing the oxide film formed on the bottom face; and
etching the trench by using the oxide film remaining on the sidewalls as an etching mask;
wherein the formation the oxide film, the removal the oxide film, and the etching of the trench are repeated at last twice.

15. A method for manufacturing a semiconductor device according to claim 12, further comprising:
forming an oxide film on an inner wall of the trench by thermal oxidation after the trench is formed;
rounding corner portions of the trench by removing the oxide film.

16. A method for manufacturing a semiconductor device according to claim 12, further comprising:
forming a silicon film in the trench by epitaxial growth after the trench is formed.

17. A method for manufacturing a semiconductor device according to claim 12, wherein the trench is formed by:
soaking the semiconductor substrate in an etching solution of the wet etching;
performing isotropic etching of the semiconductor substrate;
performing anisotropic etching of the semiconductor substrate by applying a voltage between the semiconductor substrate and the etching solution.

18. A method for manufacturing a semiconductor device according to claim 12, wherein the trench is formed by:
implanting an ion into a portion of the semiconductor substrate in which the trench is formed, before the wet etching.

19. A method for manufacturing a semiconductor devise using a semiconductor substrate comprising:
preparing a semiconductor substrate having a main surface oriented to {1 1 0} face, a first orientation flat formed on a first peripheral portion of a semiconductor substrate, and oriented to one of {1 1 1} face and {1 1 2} face perpendicular to the {1 1 0} face;
selecting {1 1 1} face on the semiconductor substrate based on the first orientation flat;
forming a trench in the semiconductor substrate by dry etching so that a longitudinal direction of the trench is defined along the {1 1 1} face;
removing a defect layer formed on a surface of the trench by wet etching.

20. A method for manufacturing a semiconductor devise according to claim 19, wherein one of potassium hydroxide (KOH) solution and tetramethylammonium hydroxide (TMAH) solution is used for the wet etching.
